(19) United States
(12) Patent Application Publication
(10) Pub. No.: US 2024/0289506 A1
(43) Pub. Date: Aug. 29, 2024

(54) METHOD OF HANDLING LARGE TRANSFORMS IN A COMPUTER-AIDED DESIGN (CAD) SOLID MODEL

(71) Applicant: Siemens Industry Software Inc., Plano, TX (US)

(72) Inventors: Peter Nanson, Cambridge (GB); Richard Collins, Cambridge (GB); Mark David William Harman, Cambridge (GB); Ben Cross, Cambridge (GB)

(21) Appl. No.: 18/568,647

(22) PCT Filed: Jun. 17, 2021
(86) PCT No.: PCT/US2021/037789

§ 371 Date: Dec. 8, 2023

(51) Int. Cl. G06F 30/12

(52) U.S. Cl. CPC G06F 30/12

(57) ABSTRACT

A computer-implemented method of handling large transforms in a computer-aided design (CAD) solid model utilizing double precision to describe a physical assembly of parts is described. If the unit size of a transform of interest exceeds a pre-determined threshold, the double precision of the transform is converted to quadruple precision whilst maintaining the double precision of the assembly. The results of any operation are output in double precision. A computer program and method of adapting an existing CAD model are also described.

The present patent document is a § 371 nationalization of PCT Application Serial No. PCT/US2021/037789, filed Jun. 17, 2021, designating the United States, which is incorporated by reference in its entirety.

### TECHNICAL FIELD

The present disclosure relates to a method of handling large transforms in a Computer-Aided Design (CAD) solid model, in particular, in a CAD solid model utilizing double precision to describe a physical assembly of parts.

### BACKGROUND

CAD systems may operate to double precision, which is based on the IEEE 754 double-precision binary floating-point format, otherwise known as binary64. A sixty-four-bit string is split into a single sign bit (bit 64), eleven exponent bits (bits 63 to 52) representing an unsigned integer from 0 to 2047, and fifty-two fraction bits (bits 51 to 0) representing a significand precision of fifteen significant digits. While the use of double precision is attractive from a computing cost perspective, it limits the precision of calculations as only fifteen significant digits are available. One effect of this is to limit the valid volume for assemblies of parts due to the loss of precision when generating relative transforms. Significantly inaccurate results may be generated for calculations involving parts that are close to each other but a long way from the origin. This primarily covers two situations: the first where a translation is applied to a part to move it a large distance from the origin and the part is rotated about the origin; and the second where a translation is applied to a part to move it a long way from the origin and the part is rotated about a point close to the newly translated position.

One manner of dealing with this reduced precision is to employ separate environments for models at different scales, which requires operation at looser tolerances for larger models. The models generated at different scales are incompatible, meaning that multiple representations of the same part at different scales are needed depending on the context, such as in the examples above. Another alternative is to employ quadruple precision throughout the CAD system. This may be using the IEEE 745-2008 128-bit base-2 format, binary 128, which includes a single sign bit (bit 128), fifteen exponent bits (bits 127 to 112) representing an unsigned integer from 0 to 16382, and one hundred and twelve fraction bits (bits 111 to 0) representing a significand precision of thirty-six significant digits, or by using a technique known as “double-double arithmetic” where pairs of double precision values are used. While quadruple precision improves the accuracy of calculations, it comes at a high computing costs, both in terms of resources and time. Aside from increased calculation times, unless increased processing power and memory space are available, any existing CAD model in double precision will need to be rewritten to operate at quadruple precision, which in itself is highly labor intensive and therefore unattractive to users. Using double-double arithmetic is limited in the magnitude of the values represented compared with quadruple precision as the number of exponent bits is still only eleven compared with fifteen. While some calculations below a particular exponent size may be only slightly less precise in double-double arithmetic than in quadruple precision, this is not the case at larger values. Consequently, a CAD system user has to choose a trade-off between the lack of interoperability between multiple environments at different scales in double precision, or the increased resources in both computing cost and labor required to upgrade the entire CAD system to quadruple precision. Alternatively, it is possible that a user inputs the transform information and is presented with an error that has to be individually debugged or overcome at runtime.

### SUMMARY

The scope of the present disclosure is defined solely by the appended claims and is not affected to any degree by the statements within this summary. The present embodiments may obviate one or more of the drawbacks or limitations in the related art.

The present disclosure aims to address these issues by providing, in a first aspect, a computer-implemented method of handling large transforms in a computer-aided design (CAD) solid model utilizing double precision to describe a physical assembly of parts. The method includes: selecting a first part in the part assembly; receiving, in double precision, input details, including a unit size, of a first transform describing the position of the first part within the assembly; receiving, in double precision, input details, including a unit size, of a second transform describing a new, second position of the first part within the assembly; if the unit size of either the first or the second transform exceeds a pre-determined threshold, converting the double precision of the first transform and the second transform into quadruple precision whilst maintaining the double precision of the assembly; operating on the combination of the first part, the first transform and the second transform to place the first part in the second position; and outputting the second position in double precision.

Using this approach means only a transform is created in or upgraded to quadruple precision and only as or when required and overcomes the need to choose between performance and accuracy, or the generation of errors that need to be resolved in a separate act, seen in existing systems.

The present disclosure also aims to address these issues by providing, in a second aspect, a computer-implemented method of handling large transforms in a computer-aided design (CAD) solid model utilizing double precision to describe a physical assembly of parts. The method includes: selecting a group of parts in the part assembly including at least a first part and a second part; receiving, in double precision, input details including a unit size of a first transform describing the position of the first part in the assembly; receiving, in double precision, input details including a unit size of a second trans-form describing the position of the second part in the assembly; if the unit size of either the first or the second transform exceeds a pre-determined threshold, converting the double precision of the first and second transform into quadruple precision and combining the first and second transforms into a relative transform whilst maintaining the double precision the assembly; operating on the combination of the group of parts and the relative transform to carry out a calculation involving all of the parts in the group; and outputting the results of the calculation in double precision.

The pre-determined threshold may be the maximum unit size of a transform available in double precision within the CAD solid model.

The first transform may be a translation matrix, and the converting includes extending a double precision representation of the translation matrix to quadruple precision.

The first transform may be a rotation matrix, and the converting includes: determining an axis-angle representation of the rotation matrix to obtain an angle θ of rotation in degrees and an axis of rotation A, both in quadruple precision; and snapping the angle of rotation θ of the axis-angle representation to quadruple precision, and, if required, snapping the axis of rotation A of the axis-angle representation to an axis normalized in quadruple precision. In this case, for angles θ of rotation in the range 175° to 185°, the converting may include diagonalizing the rotation matrix to generate an eigenvector having a value of 1; and wherein, for angles θ of rotation outside the range 175° to 185°, the converting includes solving:

$$R = I + ( sin θ ) K + ( 1 - cos θ ) {K}^{2}$$

where R is the rotation matrix through the angle of rotation θ about an axis k, I is the identity matrix, and K is the cross-product matrix for the axis k, and for angles close to a singularity arctan 2 may be used as a replacement for arccos in solving R.

The angle snapping, if required, may include computing the angle θ of rotation as an integer fraction of a circle, which corresponds to any fraction a/b when written in degrees, where a is an integer and b is an unsigned integer less than or equal to 100°.

The axis snapping may include: determining the absolute value of the axis of the axis-angle representation; iterating over a set of absolute value axes normalized in quadruple precision to determine the most appropriate absolute axis to snap to; and snapping to the actual axis by determining the appropriate signs from the absolute position of the part. Axes may include the world axes and their diagonals.

The first transform may be a reflection matrix, and the converting may include: multiplying the first transform by the negative identity matrix −I to obtain a rotation matrix; determining an axis-angle representation of the matrix to obtain an angle θ of rotation of zero and an axis of rotation A in quadruple precision; and snapping the axis of rotation A of the axis-angle representation to an axis normalized in quadruple precision.

The first transform may be a combination of at least two of a translation, a rotation, and a reflection. If the first transform is a combination of a rotation and a reflection, the converting may include: multiplying the firs transform by the negative identity matrix −I to obtain a rotation matrix; determining an axis-angle representation of the rotation matrix to obtain an angle θ of rotation in degrees and an axis of rotation A, both in quadruple precision; and snapping the angle of rotation θ of the axis-angle representation to quadruple precision. The method may further include snapping the axis of rotation A of the axis-angle representation to an axis normalized in quadruple precision.

The first transform may be applied to the part or group of parts in its local space. Alternatively, the first transform may be applied to the part or group of parts away from its local space.

Both the first transform and the second transform may have a unit size that exceeds the pre-determined threshold.

In a third aspect, a computer program is provided that includes instructions which, when the program is executed on a computer, cause the computer to carry out the method described herein.

In a fourth aspect, a method is provided for adapting an existing computer-aided design (CAD) solid model employing double precision to function in quadruple precision as and when required. The method includes providing an application programming interface between an existing computer-aided design (CAD) solid model employing double precision and the computer program.

### BRIEF DESCRIPTION OF THE DRAWINGS

The present disclosure is now described by way of example only, and with reference to the accompanying drawings, in which:

FIG. 1 illustrates an example of a data processing system in which embodiments may be implemented.

FIG. 2 is a flow chart illustrating a method carried out in accordance with an embodiment.

FIG. 3 is a flow chart illustrating a method carried out in accordance with another embodiment.

FIG. 4 is a detail from the flow chart of FIG. 2 illustrating the subset of acts performed when converting a translation matrix from double precision to quadruple precision.

FIG. 5 is a detail from the flow chart of FIG. 2 illustrating the subset of acts performed when converting a rotation matrix from double precision to quadruple precision.

FIG. 6 is a detail from the flow chart of FIG. 2 illustrating the subset of acts performed when converting a reflection matrix from double precision to quadruple precision.

### DETAILED DESCRIPTION

The embodiments described below take the approach of using a double to quadruple precision conversion as and when required to deal with large transforms. This means that rather than utilizing environments with different scales or converting an entire CAD solid model or CAD system to quadruple precision functionality, only a large transform of interest is converted from double to quadruple precision. Whether or not a transform is large is determined by whether its unit size (its size in the size units of the CAD solid model it is used in) exceeds a pre-determined threshold. For example, considering the Parasolid PLM software, available at https://www.plm.automation.siemens.com/global/en/products/plm-components/parasolid.html, the normal range of operation is 1.0-8 to 1.03 units of size, as indicated in the so-called size box provided for user input of the unit size of a transform. If a user enters a unit size that exceeds that offered by the size box, the transform is deemed to be large. Consequently, the pre-determined threshold is the maximum unit size of a transform available in double precision within the CAD solid model. As outlined below, if the unit size of the transform exceeds a pre-determined threshold, the double precision of the transform is converted to quadruple precision whilst maintaining the double precision of the part and the assembly.

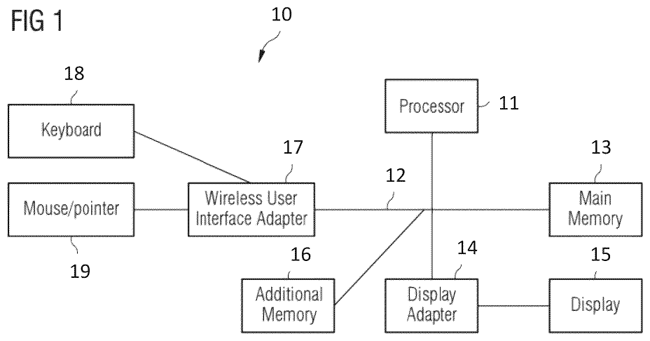

FIG. 1 illustrates an example of a data processing system in which an embodiment of the present disclosure may be implemented, for example, a CAD system configured to perform processes as described herein. The data processing system 10 includes a processor 11 connected to a local system bus 12. The local system bus connects the processor to a main memory 13 and graphics display adaptor 14, which may be connected to a display 15. The data processing system may communicate with other systems via a wireless user interface adapter connected to the local system bus 12, or via a wired network, e.g., to a local area network. Additional memory 16 may also be connected via the local system bus. A suitable adaptor, (e.g., a wireless user interface adapter 17), for other peripheral devices, (e.g., a keyboard 18, mouse 19, or other pointing device), allows the user to provide input to the data processing system. Other peripheral devices may include one or more I/O controllers such as USB controllers, Bluetooth controllers, and/or dedicated audio controllers (connected to speakers and/or microphones). Various peripherals may be connected to the USB controller (via various USB ports), including input devices (e.g., keyboard, mouse, touch screen, trackball, camera, microphone, scanners), output devices (e.g., printers, speakers), or any other type of device that is operative to provide inputs or receive outputs from the data processing system. Further, devices referred to as input devices or output devices may both provide inputs and receive outputs of communications with the data processing system. Further, other peripheral hardware connected to the I/O controllers may include any type of device, machine, or component configured to communicate with a data processing system.

An operating system included in the data processing system enables an output from the system to be displayed to the user on display 15 and the user to interact with the system. Examples of operating systems that may be used in a data processing system may include Microsoft Windows™, Linux™, UNIX™, iOS™, and Android™ operating systems.

In addition, the data processing system 10 may be implemented as in a networked environment, distributed system environment, virtual machines in a virtual machine architecture, and/or cloud environment. For example, the processor 11 and associated components may correspond to a virtual machine executing in a virtual machine environment of one or more servers. Examples of virtual machine architectures include VMware ESCi, Microsoft Hyper-V, Xen, and KVM.

Those of ordinary skill in the art will appreciate that the hardware depicted for the data processing system 10 may vary for particular implementations. For example, the data processing system 10 in this example may correspond to a computer, workstation, and/or a server. However, alternative embodiments of a data processing system may be configured with corresponding or alternative components such as in the form of a mobile phone, tablet, controller board or any other system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure.

The data processing system 10 may be connected to the network (not a part of data processing system 10), which may be any public or private data processing system network or combination of networks, as known to those of skill in the art, including the Internet. Data processing system 10 may communicate over the network with one or more other data processing systems such as a server (also not part of the data processing system 10). However, an alternative data processing system may correspond to a plurality of data processing systems implemented as part of a distributed system in which processors associated with several data processing systems may be in communication by way of one or more network connections and may collectively perform tasks described as being performed by a single data processing system. Thus, it is to be understood that when referring to a data processing system, such a system may be implemented across several data processing systems organized in a distributed system in communication with each other via a network.

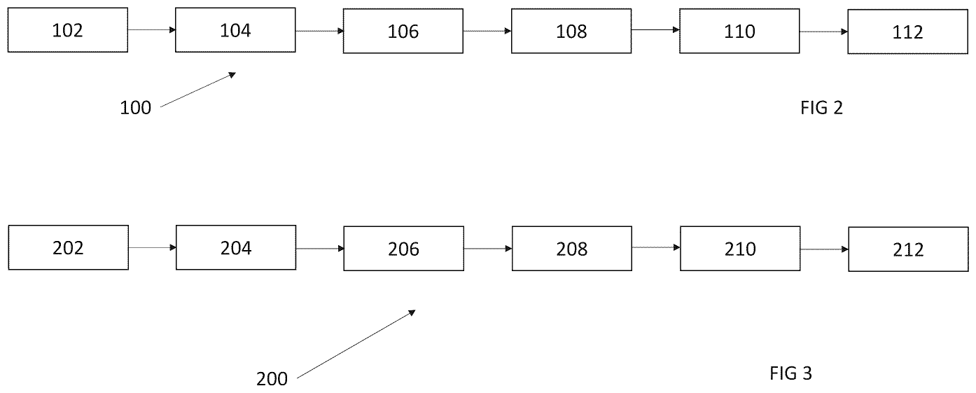

As outlined above, one issue with dealing with large transforms within CAD solid models has previously been deciding between accepting lower precision calculations with a corresponding effect on limiting the valid volume for assemblies and converting an entire assembly and model to quadruple precision. FIG. 2 is a flow chart illustrating a method carried out in accordance with a first embodiment. The method 100 takes place within a computer-aided design (CAD) solid model utilizing double precision to describe a physical assembly of parts. The assembly may be any group of parts, sub-assemblies, or the like that requires modelling as part of its manufacture or implementation in order to understand the interaction of the assembly with its environment. One example is the layout of a manufacturing line, where there is a need to be able to plan factory floorspace and positioning of elements such as robots, storage, workstations to maximize manufacturing efficiency as well as health and safety of workers.

At act 102, the method includes selecting a first part in the assembly. Because the CAD solid model employs double precision throughout, at act 104, input details of a first transform are received by the processor in double precision. This first transform describes the position of the first part within the assembly. The unit size of the first transform is provided as part of the input details and compared with the limits of the model precision, i.e., the size box. The size box represents the allowable unit size of a transform in double precision.

At act 106, input details of a second transform are received by the processor in double precision. The second transform describes a second position of the part within the assembly. Next, the ability of the embodiments to employ quadruple precision on an as and when required basis is explained.

At act 108, if the unit size of either the first or the second transform exceeds a pre-determined threshold, the double precision of both the first transform and the second transform is converted to quadruple precision whilst maintaining the double precision of the assembly. In other words, only the transforms are created in or upgraded to quadruple precision, and only if the threshold is exceeded. The remainder of the model is not affected and is maintained in double precision. The pre-determined threshold is the maximum unit size of a first transform available in double precision within the CAD solid model, as determined by the size box.

At act 110, the combination of the first part, the first transform, and the second transform is operated on, placing the first part into the second position. The second position of the first part is a different position to the first position within the assembly obtained after a translation, a rotation, a reflection, or a combination of at least two of these, as explained further below.

At act 112, the second position is output in double precision. When a large transformation is created, the quadruple precision data is stored within the transform data. This is done in a double-double precision format. One benefit of using double-double precision in this instance is that it improves compatibility with existing code that has not been upgraded to expect a quadruple precision value. The two doubles may be arranged so that only the most significant double of the double-double would be read, giving a result equivalent to there just being a (less accurate) double. The first double precision data represents the most significant bits in the quadruple format data, and the second double represents less significant bits in the quadruple format data. The second double is stored for future calculations on the transform if needed, removing the need to use any quadruple precision or double-double precision data to describe the model itself. Outputting the quadruple precision data as double precision data may be done by truncation.

FIG. 3 is a flow chart illustrating a method carried out in accordance with a second embodiment. The method 200 takes place within a computer-aided design (CAD) solid model utilizing double precision to describe a physical assembly of parts. In contrast to the first embodiment described above, rather than combining transforms in relation to a single part, the second embodiment enables the generation of relative transforms for operations in combination with pairs or groups of parts.

At act 202, the method includes selecting a group of parts in the assembly including at least a first part and second part. The group of parts is in a first condition, which includes the positions of the first and second parts and any associated geometrical information, such as their orientations. Because the CAD solid model employs double precision throughout, at act 204, input details of a first transform are received by the processor in double precision. This first transform describes the position of the first part within the group. The unit size of the first transform is provided as part of the input details and compared with the limits of the model precision, i.e., the size box. The size box represents the allowable unit size of a transform in double precision.

At act 206, input details of a second transform are received by the processor in double precision. This second transform describes the position of the second part within the group. The unit size of the second transform is provided as part of the input details and also compared with the limits of the model precision.

At act 208, if the unit size of the first or the second transform exceeds a pre-determined threshold, the double precision of the first and the second transform is converted to quadruple precision whilst maintaining the double precision of the assembly. In other words, only the transforms are created in or upgraded to quadruple precision, and only if the threshold is exceeded, the remainder of the model is maintained in double precision. This may therefore be both the first and second transform or only one of them. As above, the pre-determined threshold is the maximum unit size of a first transform available in double precision within the CAD solid model, as determined by the size box.

At act 210, the combination of the group of parts and the relative transform is operated on to carry out a calculation involving all of the parts in the group. This calculation may be to measure a distance between the parts in the group, for example. The original positions of the first and second part, and their corresponding transforms remain the same, with the relative transform in quadruple precision being used as the basis of the operation in quadruple precision.

At act 212, the results of the calculation are output in double precision. As above, when a large transformation is created, the quadruple precision data is stored within the transform data, which is also true of the calculation results. This is done in a double-double precision format, as the first double precision data representing the most significant bits in the quadruple format data, and the second double representing less significant bits in the quadruple format data. The second double is stored for future calculations on the transform if needed, removing the need to use any quadruple precision or double-double precision data to describe the model itself. Outputting the quadruple precision data as double precision data may be done by truncation. Using this method, relatively small distances between the parts may be determined accurately.

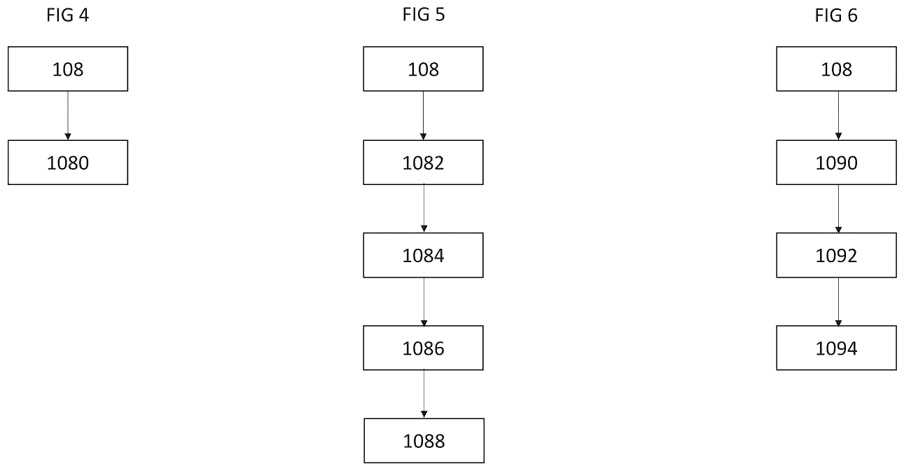

The method acts employed by various embodiments to carry out the act of converting the double precision of a transform to quadruple precision are described in more detail below with reference to FIGS. 4, 5, and 6, and the first embodiment described with respect to FIG. 2 above. However, the person skilled in the art will recognize easily that the same stages may be used to generate the relative transform in the second embodiment described above with respect to FIG. 3. Both the first and the second embodiments deal with large transforms using the same methodology.

FIG. 4 is a detail from the flow chart of FIG. 2 illustrating the subset of acts performed when converting a translation matrix from double precision to quadruple precision. The translation matrix is in a 3×3 matrix format. At act 1080, a double precision representation of a translation matrix is extended to quadruple precision. This may be done in one of a number of ways, including extending the number of significant digits by adding zeros, similar to zero padding.

FIG. 5 is a detail from the flow chart of FIG. 2 illustrating the subset of acts performed when converting a rotation matrix from double precision to quadruple precision. If a user creates a large rotation (or reflection, as described below) transform simply by entering details of the large transform into the size box, it is necessary to build the transform to a higher precision using the axis-angle information. In this situation, axis and angle snapping may be done directly from the information input by the user. However, the axis-angle information may not be available directly from the user input. This may be because the user has supplied a 3×3 matrix, or because a transform that was previously viewed as “small” (its unit size was below the size of the size box and therefore the pre-determined threshold) is upgraded from double precision to quadruple precision to be combined with a large transform. Upgrading effectively requires reverse engineer the intentions of the user who has entered a 3×3 rotation matrix in double precision and representing this accurately in quadruple precision. The ability therefore to convert double precision transformations to quadruple precision transformations even when upgrading without the original axis-angle information is a major advantage of the embodiments of the present disclosure.

Therefore, when upgrading, rather than just converting the rotation matrix from double precision to quadruple precision, the axis-angle formula is used to determine the original rotation parameters. At act 1082, an axis-angle representation of the rotation matrix is determined to obtain an angle θ of rotation in degrees and an axis of rotation A, both in quadruple precision. This may be done using Rodrigues's formula, wherein, for angles θ of rotation outside the range 175° to 185°, the converting includes solving:

$$R = I + ( sin θ ) K + ( 1 - cos θ ) {K}^{2}$$

where R is the rotation matrix through the angle of rotation θ about an axis k, I is the identity matrix, and K is the cross-product matrix for the axis k. At angles in the range 175° to 185°, the converting includes diagonalizing the rotation matrix to generate an eigenvector having a value of 1. This is because at a singularity (sin θ=0) and angles within the proximity of a singularity, dividing by sin θ leads to extremely large numbers. Empirically, this was determined to be with ±5° of 180° by carrying out a number of test cases. In addition, computing the value of cos θ from a 3×3 rotation matrix is also unstable near 0° and 180°, and therefore arctan 2 was used as a replacement for arccos in solving R.

Once the axis-angle conversion has been completed, at act 1084, the angle of rotation θ of the axis-angle representation is snapped to quadruple precision, and, if required, at act 1086, the axis of rotation A of the axis-angle representation is snapped to an axis normalized in quadruple precision. The angle snapping of act 1086 includes computing the angle θ of rotation as an integer fraction of a circle, which when written in degrees Corresponds to any fraction a/b, where a is an integer and b is an unsigned integer less than or equal to 100°. This utilizes Farey's sequence in order to determine the original angle θ of rotation parameter. Representing the angle θ of rotation as a fraction of a circle in quadruple precision is more accurate than doing so in either double precision or merely extending double precision to quadruple precision. By limiting the value of the denominator to 100° and using multiples of angles for any rotation where b>100° allows the same methodology to work successfully for quadrilaterals and other regular polygons. The axis snapping of act 1088 considers the twenty-six real-world axes, but in order not to increase computing cost rather than iterating the axis of rotation A overall twenty-six axes, iterating over a set of absolute value axes normalized in quadruple precision is done instead in order to determine the most appropriate absolute axis to snap to. Having chosen an absolute value axis, the actual axis is found by determining the absolute value of the position of the part with respect to either its local space or its origin, and determining the signs required to convert the absolute values to actual values. Axes may include the world axes and their diagonals.

FIG. 6 is a detail from the flow chart of FIG. 2 illustrating the subset of acts performed when converting a reflection matrix from double precision to quadruple precision. Therefore, if a transform is a combination of a rotation and a reflection, if the number of reflections is even the transform is a proper rotation matrix and may be converted as a rotation, and if the number of reflections is odd the transform is an improper rotation matrix and may be converted as a reflection with a non-zero angle of rotation. Similar to when considering a rotation matrix, a user enters a 3×3 reflection matrix in double precision. The difference between a rotation matrix and a reflection matrix is that a rotation matrix has a positive determinant, and that a reflection matrix has a negative determinant. Therefore, to begin the conversion process for a reflection matrix, at act 1090, the reflection matrix is multiplied by the negative identity matrix-/to obtain a rotation matrix, and the axis-angle conversion continues as above, before finally multiplying the resulting matrix by the negative identity matrix −I once again. This therefore converts the improper matrix to a proper matrix to carry out the axis snapping and restores the resulting matrix back to the original improper state. The negative identity matrix −I is an improper rotation of 180° where the axis of rotation is arbitrary. At act 1092, an axis-angle representation of the matrix is determined to obtain an angle θ of rotation of zero and an axis of rotation A in quadruple precision, and at act 1094, the axis of rotation A of the axis-angle representation is snapped to an axis normalized in quadruple precision. The angle θ of rotation is 0°, hence there is no need to carry out an angle snapping act.

Quadruple precision versions of sine and cosine functions were also implemented to improve the accuracy of calculations. Using a similar principle to iterate over seven absolute value axes, angles are pulled into the range [0, π/2], on the basis that other quadrants are either equal to or negative to this quadrant. A Taylor series is then computed for sine or cosine, taking advantage of the identity sin(x)=cos(π/2−x) to obtain a Taylor series with a small parameter. For example, for sin(1.5), instead of computing a Taylor series for sine with 1.5, faster convergence is achieved when computing a Taylor series for cosine with π/2−1.5. This also enables the Taylor series coefficients to be computed and stored hardcoded in the program code, rather than being computed on-the-fly at runtime.

One advantage offered by the embodiments is that transformations may be combined to deal with calculations involving parts that are close to each other but a long way from the origin. The transform may therefore be a combination of at least two of: a translation, a rotation, and a reflection, as illustrated in the following examples. Initially, a part in an assembly may be subject to a translation to move it a large distance away from the origin. At this point, the part may then be rotated about the origin. Thus, the translation is both large, and non-local, as the rotation transform is applied to the part away from its local space. Alternatively, the part may again be subject to a translation to move it a large distance away from the origin. However, the rotation may be applied at a distance close to the large distance away from the origin, thus rotating the part in its local space. For local rotations, it may also be desirable to snap to a non-real-world axis. It is also possible to combine translations with reflections, or rotations and reflections. For a transform that is a combination of a rotation and a reflection, if the number of reflections is even the transform is a proper rotation matrix, and if the number of reflections is odd, the transform is an improper rotation matrix. An improper rotation matrix may be represented as a reflection in an axis combined with a rotation about that same axis. An improper rotation matrix is one with a determinant of −1, then again, the reflection matrix is multiplied by the negative identity matrix −I to obtain a rotation matrix, undoing the reflection, and an additional 180° is added to the rotation. The axis-angle formula is then applied as with a rotation matrix, and the resultant rotation parameters undergo both angle and axis snapping, as above. Although the overall operation on the part in the assembly is a combination of operations, only the “large” component of the transform is created in or upgraded to quadruple precision.

Embodiments in accordance with the present disclosure also provide the ability to upgrade existing software packages of CAD solid models employing double precision to utilize the conversion to quadruple precision for large transforms as and when required. This may be done by creating an interface between an existing computer-aided design (CAD) solid model employing double precision and the computer-implemented method of handling large transforms in a computer-aided design (CAD) solid model described above. For example, by providing an API (application programming interface) between a computer program including instructions, which when the program is executed on a computer, cause the computer to carry out the embodiments disclosed herein, “plug and play” functionality may be created for an existing CAD solid model that employs double precision. This overcomes the issues of needing to rewrite existing CAD solid models to operate at quadruple precision.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method of handling large transforms in a computer-aided design (CAD) solid model utilizing double precision to describe a physical assembly of parts, the method comprising:
selecting a first part in a part assembly;
receiving, in double precision, input details of a first transform describing a position of the first part within the physical assembly, wherein the input details comprise a unit size of the first transform;
receiving, in double precision, input details of a second transform describing a new, second position of the first part within the physical assembly, wherein the input details comprise a unit size of the first transform;
converting the double precision of the first transform and the second transform into quadruple precision while maintaining the double precision of the physical assembly when the unit size of the first transform or the unit size of the second transform exceeds a pre-determined threshold;
operating on a combination of the first part, the first transform, and the second transform to place the first part in the second position; and
outputting the second position in double precision.

2. A computer-implemented method of handling large transforms in a computer-aided design (CAD) solid model utilizing double precision to describe a physical assembly of parts, the method comprising:
selecting a group of parts in a part assembly comprising at least a first part and a second part;
receiving, in double precision, input details comprising a unit size of a first transform describing a position of the first part in the physical assembly;
receiving, in double precision, input details comprising a unit size of a second transform describing a position of the second part in the physical assembly;
converting the double precision of the first transform and the second transform into quadruple precision and combining the first transform and the second transform into a relative transform while maintaining the double precision the physical assembly when the unit size of the first transform or the unit size of the second transform exceeds a pre-determined threshold;
operating on a combination of the group of parts and the relative transform to carry out a calculation involving all of the parts in the group; and
outputting results of the calculation in double precision.

3. The method of claim 1, wherein the pre-determined threshold is a maximum unit size of a transform available in double precision within the CAD solid model.

4. The method of claim 1, wherein the second transform is a translation matrix, and
wherein the converting comprises extending a double precision representation of the translation matrix to quadruple precision.

5. The method of claim 1, wherein the second transform is a rotation matrix, and wherein the converting comprises:
determining an axis-angle representation of the rotation matrix to obtain an angle θ of rotation in degrees and an axis of rotation A, both in quadruple precision; and
snapping the angle of rotation θ of the axis-angle representation to quadruple precision, and, when required, snapping the axis of rotation A of the axis-angle representation to an axis normalized in quadruple precision.

6. The method of claim 5, wherein, for angles θ of rotation in a range 175° to 185°, the converting comprises diagonalizing the rotation matrix to generate an eigenvector having an eigenvalue of 1, and
wherein, for angles θ of rotation outside the range 175° to 185°, the converting comprises solving:
R=I+(sin θ)K+(1−cos θ)K² the rotation matrix through the angle of rotation θ about an axis k, I is an identity matrix, and K is a cross-product matrix for the axis k, and wherein, for angles close to a singularity, arctan 2 is used as a replacement for arccos in solving R.

7. The method of claim 5, wherein the angle snapping comprises:
computing the angle θ of rotation as an integer fraction of a circle, which corresponds to any fraction a/b when written in degrees, where a is an integer and b is an unsigned integer less than or equal to 100°.

8. The method of claim 5, wherein the axis snapping comprises:
determining an absolute value of the axis of the axis-angle representation;
iterating over a set of absolute value axes normalized in quadruple precision to determine a most appropriate absolute axis to snap to; and
snapping to an actual axis by determining appropriate signs from an absolute position of the first part.

9. The method of claim 1, wherein the second transform is a reflection matrix, and
wherein the converting comprises:
multiplying the reflection matrix by a negative identity matrix −I to obtain a rotation matrix;
determining an axis-angle representation of the rotation matrix to obtain an angle θ of rotation of zero and an axis of rotation A in quadruple precision; and
snapping the axis of rotation A of the axis-angle representation to an axis normalized in quadruple precision.

10. The method of claim 1, wherein the second transform is a combination of at least two of: a translation, a rotation, and a reflection.

11. The method of claim 10, wherein the first transform is a combination of the rotation and the reflection, and
wherein the converting comprises:
multiplying the first transform by a negative identity matrix −I to obtain a rotation matrix;
determining an axis-angle representation of the rotation matrix to obtain an angle θ of rotation in degrees and an axis of rotation A, both in quadruple precision; and
snapping the angle of rotation θ of the axis-angle representation to quadruple precision.

12. The method of claim 11, further comprising:
snapping the axis of rotation A of the axis-angle representation to an axis normalised in quadruple precision.

13. The method of claim 1, wherein the second transform is applied to the first part or a group of parts in a local space of the first part or the group of parts.

14. The method of claim 1, wherein the second transform is applied to the first part or a group of parts away from a local space of the first part or the group of parts.

15. The method of claim 2, wherein the unit size of the first transform and the unit size of the second transform both exceed the pre-determined threshold.

16. A computer program comprising instructions, which, when the computer program is executed on a computer, cause the computer to:
select a first part in a part assembly;
receive, in double precision, input details of a first transform describing a position of the first part within a physical assembly of parts, wherein the input details comprise a unit size of the first transform;
receive, in double precision, input details of a second transform describing a new, second position of the first part within the physical assembly, wherein the input details comprise a unit size of the first transform;
convert the double precision of the first transform and the second transform into quadruple precision while maintaining the double precision of the physical assembly when the unit size of the first transform or the unit size of the second transform exceeds a pre-determined threshold;
operate on a combination of the first part, the first transform, and the second transform to place the first part in the second position; and
output the second position in double precision.

17. (canceled)

18. The method of claim 2, wherein the pre-determined threshold is a maximum unit size of a transform available in double precision within the CAD solid model.

19. The method of claim 2, wherein the second transform is a translation matrix, and
wherein the converting comprises extending a double precision representation of the translation matrix to quadruple precision.
